(19) United States
(12) Patent Application Publication
(10) Pub. No.: US 2024/0410051 A1
(43) Pub. Date: Dec. 12, 2024

(54) METHOD FOR PRODUCING A COATING ON AN OBJECT AND CORRESPONDINGLY PRODUCED COATED BODY

(71) Applicant: BOEHLERIT GmbH & Co.KG., Kapfenberg (AT)

(72) Inventors: Margarethe TRAXLER, Graz (AT); Reinhard PITONAK, Bruck an der Mur (AT); Ronald WEIßENBACHER, Bruck an der mur (AT)

(73) Assignee: BOEHLERIT GmbH & Co.KG., Kapfenberg (AT)

(21) Appl. No.: 18/698,210

(22) PCT Filed: Jan. 12, 2023
(86) PCT No.: PCT/AT2023/060008

§ 371 Date: Apr. 3, 2024

(30) Foreign Application Priority Data
Mar. 3, 2022 (AT) A 50140/2022

(51) Int. Cl. C23C 16/30; C23C 28/04

(52) U.S. Cl. CPC C23C 16/303; C23C 28/044

(57) ABSTRACT

A method for producing a coating on an object and a correspondingly produced coated body, in particular a cutting insert such as a cutting plate for machining processes. The coating with one or more coating layers is applied to the object. At least one Al₁₋ₓTiₓN coating layer is deposited using a CVD method, wherein nitrogen in the Al₁₋ₓTiₓN coating layer can be partially substituted. In order to obtain a coating layer with a highest possible proportion of cubic phases, the Al₁₋ₓTiₓN coating layer is deposited in the presence of a sulfur-containing gas.

The invention relates to a method for producing a coating on an object, in particular a cutting insert such as a cutting plate for machining processes, wherein a coating with one or more coating layers is applied to the object, wherein at least one Al₁₋ₓTiₓN coating layer is deposited using a CVD method, wherein nitrogen in the Al₁₋ₓTiₓN coating layer can be partially substituted.

The invention furthermore relates to a coated body.

From the prior art, it is known that cutting tools or cutting inserts are coated with coating layers that are composed of titanium, aluminum, and nitrogen in order to increase a service life in the cutting application. In this regard, reference is often generally made to TiAlN coating layers, wherein an average chemical composition is specified by Ti₁₋ₓAlₓN (with x>0), regardless of whether one or more phases are present in the coating layer. For coating layers which contain more aluminum than titanium in terms of an average overall composition, the nomenclature AlTiN, or more precisely AlₓTi₁₋ₓN, is also common (with x>0.50).

From WO 03/085152 A2, the production of monophasic coating layers with a cubic structure in the AlTiN system is known, wherein at a relative aluminum nitride (AlN) content of up to 67 mole percent (mol %), a cubic structure of the AlTiN is obtained. At higher AlN contents of up to 75 mol % a mixture of cubic AITiN and hexagonal AlN is produced, and at an AlN content of more than 75 mol % exclusively hexagonal AlN and cubic titanium nitride (TiN) are produced. According to the document cited, the described AlTiN coating layers are deposited by means of physical vapor deposition (PVD). With a PVD method, maximum relative AlN contents are thus virtually limited to 67 mol %, since otherwise a shift into phases that only contain aluminum in the form of hexagonal AlN is possible. However, a higher relative content of AlN in a cubic phase is, according to expert opinion, desirable in order to maximize a wear resistance to the greatest possible extent.

Historically, therefore, attempts were made to overcome these disadvantages of the PVD methods and, from the prior art, the use of chemical vapor deposition (CVD) in place of PVD methods is also known, wherein a CVD method is to be carried out at relatively low temperatures within the temperature window of 700° C. to 900° C., since cubic AlTiN coating layers cannot be produced at temperatures of ≥1000° C., for example, due to the metastable structure of this type of coating layers.

If necessary, the temperatures can also be even lower according to U.S. Pat. No. 6,238,739 B1, namely within the temperature window of 550° C. to 650° C., although high chlorine contents in the coating layer must be accepted, which proves disadvantageous for an application case.

Attempts have therefore been made to optimize CVD methods such that AlTiN coating layers with a high aluminum content and a cubic structure of the coating layer can be produced with said methods (I. Endler et al., Proceedings Euro PM 2006, Ghent, Belgium, 23 to 25 Oct. 2006, Vol. 1, 219). Even though these coating layers have a high microhardness, and therefore fundamentally advantageous properties for a high wear resistance during use, it has nevertheless been shown that an adhesive strength of coating layers of this type can be too low. In light of this, it was therefore proposed in DE 10 2007 000 512 B3 that a 1-μm thick coating layer that is formed as a phase gradient layer and composed of a phase mix of hexagonal AlN, TiN and cubic AITiN be provided beneath a cubic AlTiN coating layer that is 3 μm thick, wherein a cubic AlTiN content has an increasing proportion with an AlTiN coating layer that is outwardly cubic, or towards the (exclusively) cubic AlTiN coating layer. Cutting plates coated in such a manner were used to mill steel, although only slight improvements in a wear resistance were achieved compared to coating layers that were produced by means of a PVD method.

In addition to the merely slight improvement in a wear resistance, a further disadvantage of a bonding layer according to DE 10 2007 000 512 B3 is that the bonding or phase gradient layer grows extremely quickly, even in experiments on a laboratory scale (I. Endler et al., Proceedings Euro PM 2006, Ghent, Belgium, 23 to 25 Oct. 2006, Vol. 1, 219). In the case of production in a larger reactor that is designed for an industrial coating of cutting plates, this leads to the bonding or phase gradient layer becoming extremely thick in the provided coating process, since a temperature for forming the ultimately intended cubic AlTiN must be reduced, which requires adequate time.

During this reduction of process temperature, however, a thickness of the bonding or phase gradient layer increases rapidly, since a fast cooling is not possible in an industrial reactor. It would be conceivable to interrupt the coating process for a longer period or to interrupt the cooling, but this is not cost-efficient. The phase gradient layer thus results not only in additional effort for marginal improvement of performance; rather, it is also difficult to manage.

In the production of AlTiN coating layers by means of a CVD method and the optimization thereof, the goal initially taken as a starting point was that wear-resistant and oxidation-resistant, and therefore optimal, coating layers can be obtained if an aluminum content in the coating layer is as high as possible and, wherever possible, the coating layer has an entirely cubic structure.

In this regard, the formation of AlTiN coating layers became known from WO 2012/126030 A1, wherein the AlTiN coating layers can be formed with a predominantly cubic structure. However, in the AlTiN coating layer, additional phases can also be present, for example hexagonal AlN. Interestingly enough, it has been shown that lamellar structures can also be present inside corresponding AITIN coating layers. Cutting plates coated with AlTiN coating layers of this type result in significantly improved service life in comparison with conventional PVD-coated cutting tools.

In further studies, it was possible, according to WO 2013/134796 A1, to produce AlTiN coating layers that are at least partially formed with a lamellar structure inside of the AITiN coating layers, wherein it has been shown that the lamellae are composed of alternating regions of differing composition, wherein a hexagonal, high-aluminum phase is arranged such that it alternates in segments with a cubic, high-titanium phase. Surprisingly, it was found that, with correspondingly coated cutting tools, it was possible to achieve extraordinarily good results in terms of service life for milling, even though hexagonal aluminum nitride is present. This can likely be attributed to the special lamellar formation in which the inherently softer hexagonal aluminum nitride is clearly not particularly disadvantageous.

In further attempts to study, and possibly to improve, such AlTiN coating layers or, more precisely, Al₁₋ₓTiₓN coating layers, and to also understand the mechanisms behind them, it was possible, according to WO 2016/112417 A1 to discover that, through targeted variation of a ratio of the precursors for titanium and aluminum under predefined reaction conditions in terms of temperature, pressure, and gas compositions and gas flow rates, a sequence of the lamellae formation with alternating layers having higher aluminum content and higher titanium content can be adjusted in a targeted manner. For very high aluminum contents, it is possible, according to WO 2016/112417 A1, to obtain structures with lamellae of alternating hexagonal and cubic segments with higher aluminum contents, whereas with lower aluminum contents, structures can be obtained in which the individual segments each have a cubic structure. The corresponding mechanism was subsequently elucidated in several scientific publications (A. Köpf et al., Nanostructured coatings for tooling applications, Mat. Sci. Forum, Vols. 825-826 (2015) 599; A. Köpf et al., Nanostructured coatings for tooling applications, Int. Journal of Refractory Metals and Hard Materials, 62, (2017) 219).

The original work on Al₁₋ₓTiₓN coating systems had the objective of depositing as much aluminum as possible in the Al₁₋ₓTiₓN coating layers in order to thereby obtain a high oxidation resistance, while retaining a cubic structure wherever possible. As has become evident in accordance with the above citations, however, there occurs in the case of comparatively high aluminum contents a formation of a lamellar structure with alternating hexagonal, high-aluminum segments on the one hand and cubic, high-titanium segments on the other hand. The corresponding structures are very well suited to machining, though it would be desirable to be able to stabilize solely cubic structures in an Al₁₋ₓTiₓN coating layer, that is, those with alternating cubic segments having higher aluminum content and cubic segments having higher titanium content, even with a higher average aluminum content. This could possibly result in an improvement in the service life of correspondingly coated tools such as cutting plates, for example.

This is addressed by the invention. The object of the invention is to further develop a method of the type named at the outset such that a coated object can be provided, in particular a cutting insert such as a cutting plate, which has an Al₁₋ₓTiₓN coating layer that is formed with a high wear resistance.

A further object is to present a correspondingly produced body of the type named at the outset.

The method-related object is attained if, in a method of the type named at the outset, the Al₁₋ₓTiₓN coating layer is deposited in the presence of a sulfur-containing gas.

One advantage obtained with a method according to the invention can be seen in that a coated object can be provided, in particular a cutting element such as a cutting plate, or a different cutting element or tool, which has a high wear resistance during use, in particular during a machining of workpieces, for example a lathing or milling. Surprisingly, it was found that the presence of a sulfur-containing gas results in a lamellar structure in Al₁₋ₓTiₓN coating layers being stabilized with a cubic structure, that is, cubic segments which directly follow cubic segments, but have different chemical compositions. This means that, with the presence of a sulfur-containing gas during the deposition process or a CVD coating step, a corresponding cubic formation of the lamellar structure with higher aluminum contents can be stabilized. An exact mechanism for this is not yet known. Compared to a process management without the presence of a sulfur-containing gas, however, it is apparent that, viewed overall, more cubic phase is present, or that with the use of a sulfur-containing gas a cubic structure in the direction of higher aluminum contents (in relation to the overall composition of the Al₁₋ₓTiₓN coating layer) can be obtained. Higher aluminum contents, in turn, promote the oxidation resistance, and therefore also a wear behavior, during machining operations in which high temperatures occur, for example a lathing or milling of workpieces made of a metal or an alloy.

Sulfur is present in a correspondingly produced Al₁₋ₓTiₓN coating layer. The Al₁₋ₓTiₓN coating layer can be embodied such that nitrogen is partially substituted. Carbon and/or oxygen can in particular be used for the substitution. Regardless of the type of substitute for nitrogen, however, it is preferably provided that no more than 10% of the nitrogen atoms are replaced by carbon and/or oxygen. It is surmised that sulfur is also available as a substitute for the nitrogen, though it could also be that, within the coating layer, for example, fine sulfides are deposited separately which, during the deposition of the Al₁₋ₓTiₓN coating layer, facilitate a formation of a lamellar structure with solely, or at least predominantly, alternating cubic segments.

In principle, different sulfur-containing gases are used in a method according to the invention, for example thiols, which degrade at the process temperatures of normally more than 700° C. Another possible source of sulfur is carbon disulfide. However, for the sake of a simple process management, it is preferably provided that hydrogen sulfide is used as sulfur-containing gas. Hydrogen sulfide is easy to handle and is already present in gaseous form; it can thus be fed to the reaction zone with the other gases without difficulty.

According to the preferred embodiment with alternating segments of a respectively cubic structure, it is advantageously provided that the Alt-«TiₓN coating layer is deposited with a hexagonal aluminum nitride (AlN) volume proportion of less than 20 percent by volume (hereinafter abbreviated as: vol %), preferably less than 10 vol %, in particular less than 5 vol %. However, specific proportions of hexagonal AlN can be provided, for example more than 1 vol %. The hexagonal AlN can thereby either be present in lamellae (wherein aluminum can be partially substituted by titanium) and/or as separate hexagonal AlN.

The Al₁₋ₓTiₓN coating layer is advantageously deposited as an outermost coating layer. The outermost coating layer is normally a working layer which comes into contact with the material that is to be worked, for example a cast material. Because the Al₁₋ₓTiₓN coating layer is extremely wear resistant, it is expedient that it constitutes an outermost coating layer. However, it is also possible that one or more additional coating layers are deposited on the Al₁₋ₓTiₓN coating layer. Oxide layers, for example, can be used for this purpose, or even less wear-resistant coating layers, for example of cubic titanium nitride.

It is advantageously provided that one or more coating layers are deposited beneath the Al₁₋ₓTiₓN coating layer, wherein preferably all coating layers are deposited using a CVD method. The one or more of the coating layers deposited beneath the Al₁₋ₓTiₓ coating layer are, on the one hand, used for bonding to a substrate, typically a cemented carbide or possibly also a high-speed steel, and, where necessary, also for further optimizing the coating as a whole in terms of a wear resistance. Normally, a coating layer of titanium nitride is used as a direct bonding layer on a base body, for example a base body made of a cemented carbide. The bonding layer of titanium nitride normally has a thickness of no more than 2 μm and is deposited using a CVD method. The Al₁₋ₓTiₓN coating layer can then directly be provided, but at least one additional (intermediate) layer can also still be provided. Said intermediate layer can, in particular, be a coating layer of titanium carbonitride (TiCN). In particular, MT-TiCN, which is known to the ordinarily skilled artisan, can be used for this purpose, wherein MT stands for medium temperature, that is. TiCN that is deposited at relatively low temperatures. In principle, the bonding layer of TiN is sufficient, so that it is possible to omit intermediate layers, which enables a more effective and material-saving production.

Where provided, it is preferred that a TiCN coating layer is deposited at a temperature of 800° C. to 880° C. In principle, lower temperatures could also be chosen for the production of the TICN coating layer with elongated crystals, though in that case a heating would need to then once again take place in order to deposit the coating layer with AlₓTi₁₋ₓN.

The optionally provided TiCN coating layer is expediently deposited with a thickness of up to 7 μm, preferably 2 μm to 5 μm. A corresponding thickness is sufficient in order to impart to the coating as a whole a necessary toughness, or to avoid potential tensile and/or compression stresses to the greatest possible extent. A certain toughness of the coating as a whole is also necessary because the coating layer with AlₓTi₁₋ₓN has a high hardness and therefore a rather low toughness.

The production of the TiCN coating layer can occur as is known per se from the prior art. In this regard, the TiCN coating layer is expediently deposited from a gas containing or composed of nitrogen, hydrogen, acetonitrile and titanium tetrachloride. In order to control in a targeted manner a thickness of this coating layer at the comparatively high temperatures for the deposition of the TiCN coating layer of 800° C. to 880° C., the gas can, in contrast to the prior art, be used with a higher nitrogen proportion than hydrogen proportion, whereby a deposition rate can be kept low.

In this regard, it is expedient that the nitrogen proportion is at least twice, preferably at least four times, in particular six times, the hydrogen content. The coating layer with AlₓTi₁₋ₓN is preferably deposited at a temperature equal to or below a temperature of a deposition of the TiCN coating layer. A process for producing a coating can thus be efficiently designed with regard to a temperature control. It is then possible, starting from an initial temperature, to continuously lower the temperature during a producing of the coating layer, wherein an advantageous coating can be obtained within a short time. A TiCN coating layer thus created has crystals that are elongated in cross section, which crystals preferably disperse mainly at an angle of +30° to a surface normal of the coated area. An average composition TiCₐN₁₋ₐ has a range of 0.3 to 0.8, in particular 0.4 to 0.6 for the index a.

In addition, it is also possible that multiple Al₁₋ₓTiₓN coating layers are deposited which are separated by additional coating layers. An alternating layer structure is thus constructed in which the Al₁₋ₓTiₓN coating layers are alternately arranged with additional coating layers. The additional coating layers can, taken individually, be identically or differently embodied. Advantageously, an alternating embodiment is designed with an identical coating layer, so that an abstract sequence A-B-A-B, etc. is given, wherein A stands for the Al₁₋ₓTiₓN coating layer and B stands for the additional coating layer. The additional coating layer can be an oxidic coating layer, for example.

In terms of the method, it is preferred that the Al₁₋ₓTiₓN coating layer is deposited from a first mixture of nitrogen, hydrogen, titanium tetrachloride, aluminum trichloride, and hydrogen sulfide and from a second mixture of nitrogen and ammonia. The two mixtures are fed separately to a reaction zone. The reaction zone can, in particular, be the interior of a reactor, for example of an industrial reactor. Reactors of this type for CVD methods are known to the ordinarily skilled artisan and are sold under the brand name Bernex®, for example. A separate feed of the reactive gases to a reaction zone of the reactor using titanium tetrachloride and aluminum trichloride on the one hand and ammonia on the other hand is expedient, since a reaction of the metal chlorides with ammonia takes place rapidly, and since otherwise there is the risk of feed lines becoming blocked. The hydrogen sulfide provided is thereby expediently fed with the first mixture.

The reactor used can essentially be embodied in a cylindrical shape as a vertical reactor in which the objects that are to be coated, in particular cutting plates, are arranged in horizontal planes. What are referred to as trays are used for this purpose. The cutting plates can also be positioned in a suspended manner in planes transverse to a vertically extending longitudinal axis of the reactor. With the corresponding vertical embodiment of the reactor, feeds for the two gas mixtures can then be provided centrally, wherein the gas mixtures enter the reaction zone of the reactor from the pipes, roughly in the planes of the arranged objects that are to be coated. It is thus ensured that the separately fed, reactive gases are first able to mix in the actual reaction zone of the reactors.

The Al₁₋ₓTiₓN coating layer is preferably deposited at a temperature of 800° C. to 850° C. preferably 810° C. to 830° C. This temperature range for the deposition is excellently suited to producing the desired structures.

A pressure in the reaction zone or during the deposition of the Al₁₋ₓTiₓN coating layer is advantageously set to 10 mbar to 80 mbar, in particular 15 mbar to 40 mbar.

The Al₁₋ₓTiₓN coating layer is preferably produced at least partially with regions of lamellae, wherein the lamellae preferably have an average size, determined according to Debye-Scherrer, of less than 150 nm, preferably less than 100 nm, in particular less than 80 nm. An embodiment of the Al₁₋ₓTiₓN coating layer with lamellae has proven to be a particularly favorable structure for coatings for machining tools, for example cutting plates or the like. Here, it can also be the case that a lamellar structure is only present in regions. However, it is inherently beneficial if at least the main part, that is, more than 50 vol %, of the Al₁₋ₓTiₓN coating layer is embodied with the preferential lamellar structure. A corresponding verification can be established without difficulty in a cross section using imaging methods. Fundamentally, a finest possible formation of the lamellar structure is preferred.

For example, the lamellae can be embodied with a thickness of 15 nm to 75 nm, in particular approximately 20 nm to 65 nm.

In principle, any desired objects can be coated with an Al₁₋ₓTiₓN coating layer. For diverse applications, however, it is an advantage if an object or body made of a cemented carbide is directly or indirectly coated. Particularly for tools which are used in air at high temperatures, and are therefore also subjected to an oxidative load in addition to the high temperatures, cemented carbides prove to be resistant. This applies in particular to tools such as cutting plates for lathing, drilling, and/or milling operations.

Though a method according to the invention is designed such that an object made of a cemented carbide is advantageously coated, other objects which are subjected to abrasive, thermal, and/or oxidative wear during use can, as mentioned, also be coated. Forming tools, stamping tools, rollers, or other tools for forming work are noted merely as examples hereof.

The other object of the invention is obtained if, with a coated body of the type named at the outset, the Al₁₋ₓTiₓN coating layer comprises sulfur. The coated body can thereby be produced in particular using a method according to the invention, or the method according to the invention can be applied for this purpose.

A body according to the invention in particular has the advantage that it can be embodied with a comparatively high aluminum content while maintaining an at least predominantly cubic structure within the Al₁₋ₓTiₓN coating layer. A correspondingly coated body can therefore advantageously be used in particular for operations or processing steps which involve a high thermal and oxidative load on the body, typically a tool such as a cutting plate or another cutting element.

Because of the preferred embodiment with a cubic structure of the Al₁₋ₓTiₓN coating layer, at least predominantly, advantageously more than 70 vol %, in particular more than 85 vol %, there normally also results a small volume proportion of hexagonal AlN. Advantageously, a hexagonal AlN volume proportion of less than 20 vol %, preferably less than 10 vol %, in particular less than 5 vol % is provided. The hexagonal AlN can thereby be present either in the lamellar structure, where it can be present as a segment having hexagonal AlN that comprises or can comprise a partial substitution of the aluminum by titanium, or as separate AlN in addition to the lamellae, wherein in the latter case the aluminum can also be partially substituted by titanium.

A proportion of sulfur in the Al₁₋ₓTiₓ—N coating layer is normally less than 5 atomic percent (hereinafter abbreviated as: at %), preferably less than 4 at %, in particular less than 3 at %. Sulfide enters the Al₁₋ₓTiₓN coating layer through the production process, in particular using a method according to the invention, and, from a process technology standpoint, is provided in order to obtain an advantageous structure or formation of the Al₁₋ₓTiₓN coating layer. Basically, it is not assumed that sulfur takes on a functional purpose in the Al₁₋ₓTiₓN coating layer itself, but rather beforehand during the deposition of the Al₁₋ₓTiₓN coating layer using CVD. It therefore appears to be expedient that sulfur is only present in contents which are necessary in the preceding step of deposition in order to obtain a desired structure. Therefore, the sulfur proportion is advantageously kept as low as possible. However, a certain minimum content results from the provided process management, which permits a formation of a lamellar structure with alternating cubic lamellae segments of differing composition up to higher aluminum contents than previously allowed.

It is preferably provided that the Al₁₋ₓTiₓN coating layer is at least partially embodied with regions of lamellae, wherein the lamellae preferably have an average size, determined according to Debye-Scherrer, of less than 150 nm, preferably less than 100 nm, in particular less than 80 nm. As stated above, a thinnest possible embodiment of the lamellae is expedient with regard to good use properties, in particular for a machining.

In a correspondingly coated object, an aluminum proportion can, in relation to an average composition Al₁₋ₓTiₓN of the Al₁₋ₓTiₓN coating layer, be relatively high, and preferably lies in the range of X=0.85 to 0.99, preferably in the range of 0.885 to 0.975, in particular in the range of 0.89 to 0.95.

Additional features, advantages, and effects of the invention follow from the exemplary embodiment described below. In the drawings which are thereby referenced:

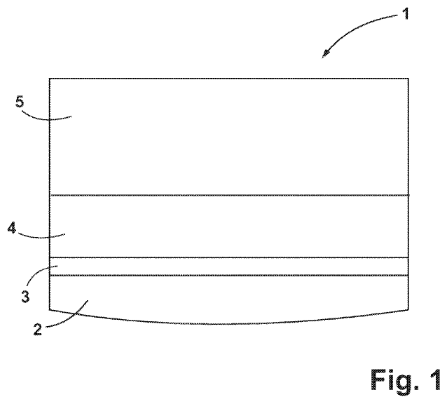

FIG. 1 shows a schematic illustration of a coated cutting plate;

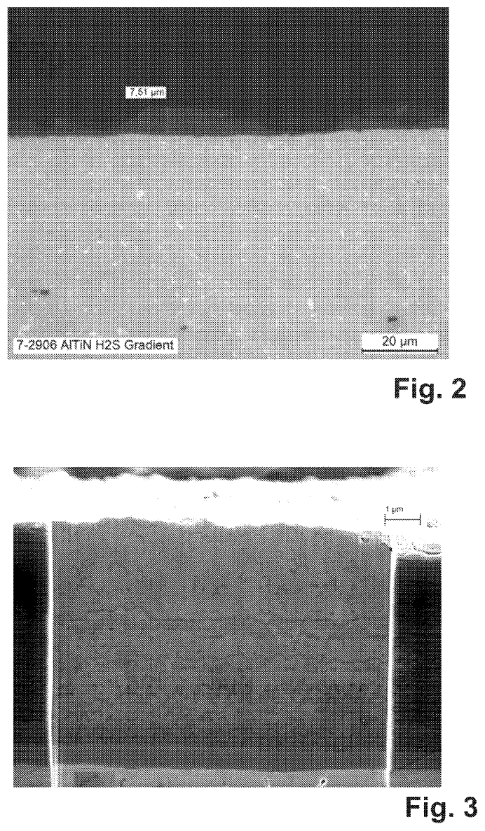

FIG. 2 shows an image of a coated cemented carbide body taken using scanning electron microscopy;

FIG. 3 shows a further image of a coated cemented carbide body taken using scanning electron microscopy;

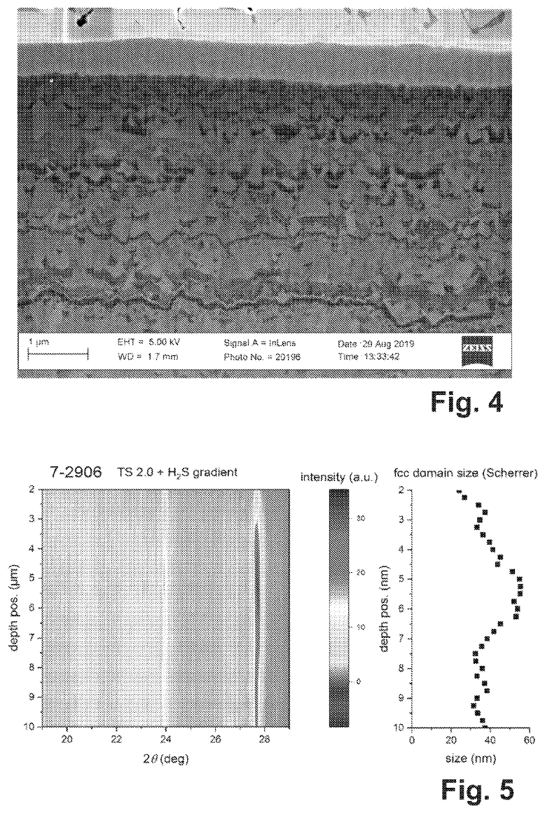

FIG. 4 shows an image of a coated cemented carbide body with an Al₁₋ₓTiₓN coating layer having different proportions of sulfur, taken using scanning electron microscopy;

FIG. 5 shows a visual representation of reflections in an X-ray diffractogram as a function of an H₂S concentration during a deposition of a coating layer according to FIG. 4 as well as the related domain size according to Debye-Scherrer:

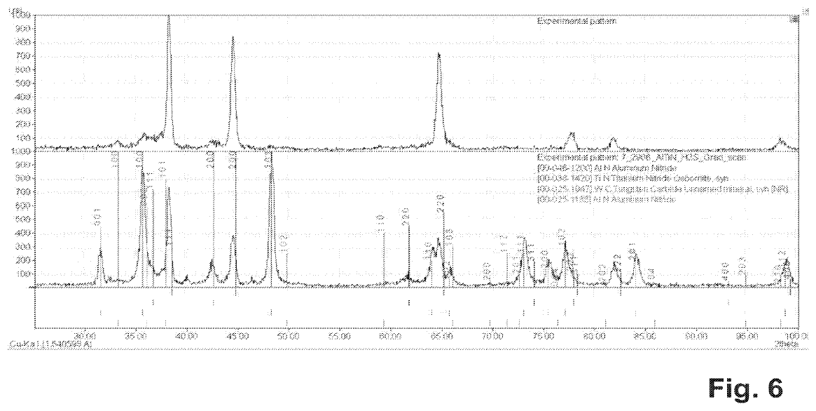

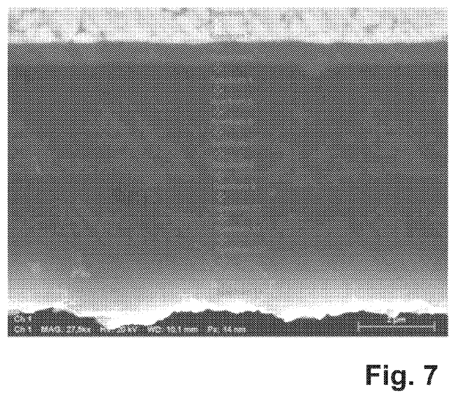

FIG. 6 shows an X-ray diffractogram;

FIG. 7 shows a further image taken using scanning electron microscopy, with positions indicated for spectra;

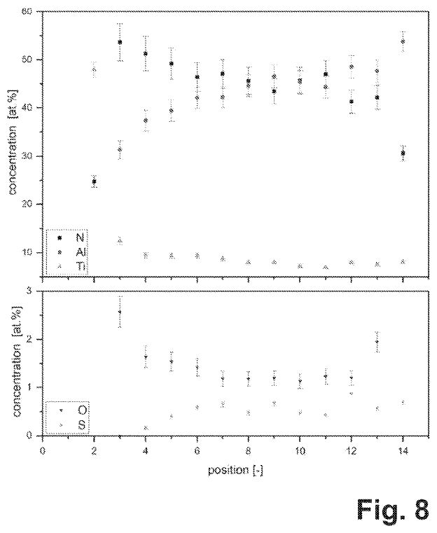

FIG. 8 shows diagrams pertaining to oxygen contents and sulfur contents at the spectral positions indicated in FIG. 7.

In FIG. 1, a body 1 or object is illustrated by way of example. The object is a cutting element, but can also be a different body 1. The body 1, which is merely illustrated in section, comprises a base body 2. The base body 2 is normally formed from a cemented carbide. The cemented carbide can, for example, be a cemented carbide based on tungsten carbide as a hard material, wherein the tungsten carbide can be partially replaced by titanium carbide. In addition, a metallic binder is provided, typically cobalt, though nickel and/or iron, possibly in combination with one of the other metallic binders, for example cobalt and iron, or all of these metals, can also be provided. Typically, a proportion of hard material, for example tungsten carbide, as mentioned, is 85% to 95%. The remainder is essentially formed from the metallic binder.

The base body 2 is provided with a multi-layer coating, wherein a first coating layer 3 is formed from titanium nitride (TIN). The TiN coating layer serves as a bonding layer. The bonding layer normally has a layer thickness of no more than 2 μm. An additional coating layer 4 of MT-TiCN is deposited on the bonding layer of TIN. This coating layer can have a thickness of 2 μm to 7 μm, for example, but is merely optional. Finally, one other additional coating layer 5 is deposited on the MT-TiCN coating layer. Said additional coating layer 5 is formed from Al₁₋ₓTiₓN coating layers. This additional coating layer 5 can, as illustrated, constitute the outermost coating layer, which is not mandatory, however. It is also possible that, on this additional coating layer 5, at least one additional coating layer is also deposited on the outer side.

For the production of the Al₁₋ₓTiₓN coating layer, the base body 2 is first supplied and the bonding layer of TiN is then deposited, whereupon the additional coating layer 4 of MT-TiCN is, where provided, applied at reduced temperature. Finally, the coating layer of Al₁₋ₓTiₓN is deposited at a once again reduced temperature. All coating layers are, even if still others should be provided, deposited in the CVD process, so that all coating layers can be created in a reactor in one procedure by simply reducing the temperature and switching the process gas.

In the production of the Al₁₋ₓTiₓN coating layer, two reaction gases are separately fed to the reactor, where they are allowed to react in the reaction zone. This can be achieved if, for example, separate feed pipes open into the reactor with corresponding outlets. A first mixture of a reaction gas is thereby composed of nitrogen, hydrogen, titanium tetrachloride, aluminum trichloride, and hydrogen sulfide. The titanium tetrachloride is thereby supplied on the basis of liquid titanium tetrachloride. The aluminum trichloride is created in situ for the reaction, in that hydrochloric acid is conducted over aluminum pellets. The second mixture is composed of ammonia and nitrogen and is guided into the reaction zone separately from the first mixture, where it can then react with the first mixture, wherein the Al₁₋ₓTiₓN coating layer forms.

In Table 1 below, typical reaction conditions are presented. If no MT-TicN coating layer or other intermediate layer is provided, which is advantageous for a simplest possible coating system, only the TiN bonding layer is provided.

TABLE 1
Typical reaction conditions for an Al₁₋ₓTiₓN
coating layer (for H₂S, see Table 3 in detail)

| Coating | Temperature | Gas composition/Gas flow rate (L/min), |
|---|---|---|
| layer | (° C.) | or TiCl₄ and CH₃CN (mL/min) |
| TiN | 880-900 | TiCl₄/2.7, N₂/14, H₂/17 |
| MT-TiCN | 830-870 | CH₃CN/0.5, TiCl₄/2.7, N₂/19, H₂/3 |
| AlTiN | 800-830 | HCl—AlCl₃/2.7-0.9, TiCl₄/0.3, |
| | | NH₃—N₂/0.9-4.5, H₂/64, H₂S variable |

In Table 2 below, general parameters corresponding to deposited coating layer are presented by way of example.

TABLE 2
General parameters of the coating layers

| | Layer thickness (μm) | | |
|---|---|---|---|
| Coating layer | General | Preferred | Composition |
| TiN | ≤2 | 0.25-0.75 | TiN |
| MT-TiCN | 1-10 | 2-5 | TiCₐN₁₋ₐ, a = 0.4-0.6 |
| AlTiN | 1-10 | 3-8 | AlₓTi₁₋ₓN, x = 0.80-0.99 |

In order to examine an influence of hydrogen sulfide during the deposition of Al₁₋ₓTiₓN coating layers corresponding to the preceding statements, an Al₁₋ₓTiₓN coating layer was produced with a varying content of hydrogen sulfide during the deposition. In Table 3 below, corresponding reaction conditions are stated in detail, wherein a TiAlN coating layer is provided as a bonding layer.

TABLE 3
Reaction conditions for the deposition of Al₁₋ₓTiₓN
coating layers in the presence of hydrogen sulfide.

| | | TiN | AlTiN | AlTiN |
|---|---|---|---|---|
| Batch temperature | [° C.] | 890 | 800 | 800 |
| AlCl₃ temperature, generator | [° C.] | 365 | 365 | 365 |
| AlCl₃ flow rate | [L/min] | 0 | 1.2 | 1.2 |
| H₂S flow rate | [mL/min] | 0 | 0 | 10* |
| HCl flow rate | [L/min] | 0 | 0.35 | 0.35 |
| N₂ flow rate | [L/min] | 14 | 5.5 | 5.5 |
| H₂ flow rate | [L/min] | 17 | 61 | 61 |
| TiCl₄ flow rate | [mL/min] | 2.2 | 0.7 | 0.7 |
| NH₃ flow rate | [L/min] | 0 | 1 | 1 |
| Pressure | [mbar] | 160 | 23 | 23 |

*The H₂S bypass is subsequently increased in steps by 10 mL/min each, ultimately to 100 mL/min, so that a gradient layer results.

In FIG. 2, an image taken using scanning electron microscopy is shown in which a corresponding coating layer can be seen on a cemented carbide body. The coating layer was deposited in the presence of hydrogen sulfide at a varying content, as noted for Table 3.

In FIG. 3, a correspondingly produced Al₁₋ₓTiₓN coating layer is depicted in an enlarged manner using scanning electron microscopy. The Al₁₋ₓTiₓN coating layer comprises lamellae that have a lamellar thickness (sum of the segments of one higher-aluminum segment and one higher-titanium segment each) of less than 100 nm, as is known from corresponding coating layers. In FIG. 4, this is shown in further enlargement, and is once again visible.

FIG. 5 shows a visual representation of reflections in an X-ray diffractogram as a function of an H₂S concentration during a deposition of a coating layer according to FIG. 4 as well as the related domain size according to Debye-Scherrer. As can be seen, the typical cubic reflections become stronger as the H₂S concentration increases, which indicates that the cubic phases are stabilized by an increasing H₂S concentration. The domain size shows a certain fluctuation, but it can be observed that the lamellae size runs in the range of approximately 20 nm to 60 nm. It can be stated that the presence of H₂S facilitates the formation of cubic phases, that is, lamellae with alternating cubic segments of higher aluminum concentration and cubic segments of higher titanium concentration. This, in turn, introduces the possibility of creating corresponding coating layers with higher aluminum contents, since a collapse into the hexagonal AlN structure is opposed. The formation of a correspondingly cubic structure is confirmed in the X-ray diffractogram, as is shown in FIG. 6.

The sulfur contents in the Al₁₋ₓTiₓN coating layer are relatively low and lie, as can be seen in FIG. 7 viewed in combination with FIG. 8, below an oxygen concentration in the Al₁₋ₓTiₓN coating layer. In FIG. 7, a corresponding coating layer can be seen, wherein different measurement positions for spectra are recorded, and wherein the measurement positions are accompanied by an increasing H₂S content in the first reaction mixture. As can be seen in FIG. 8, an aluminum content in the created Al₁₋ₓTiₓN coating layer also increases as the H₂S concentration increases. The sulfur content remains in a predetermined range within statistical significance.

Cutting plates with a coating system according to FIG. 1 or as described above were produced in the presence of hydrogen sulfide during the deposition of the Al₁₋ₓTiₓN coating layer and compared with analogous coated cutting plates produced, however, without the presence of hydrogen sulfide during the deposition. Corresponding machining results are presented in Table 4 below.

TABLE 4
Machining results

| | KV/K factor | Wear V_{b} at cm³ | | | | | | | | |
|---|---|---|---|---|---|---|---|---|---|---|
| Cutting plate | mm | 250 | 500 | 750 | 1000 | 1250 | 1500 | 1750 | 2000 | Total |
| Invention 1 | 0.0296/1.047 | 0.070 | 0.079 | 0.086 | 0.108 | 0.121 | 0.156 | | | 1500 |
| | | | 0.095 | | 0.102 | 0.102 | 0.102 | 0.105 | 0.105 | |
| Invention 2 | 0.0337/1.209 | 0.073 | 0.079 | 0.092 | 0.124 | 0.137 | 0.163 | | | 1500 |
| | | | 0.099 | | 0.105 | | 0.121 | | 0.134 | |
| Comparison 1 | 0.0424/1.167 | 0.029 | 0.048 | 0.086 | 0.089 | 0.092 | 0.096 | 0.099 | 0.105 | |
| | 0.0432/1.189 | | 0.076 | | 0.077 | | 0.083 | | 0.093 | |
| Comparison 2 | 0.0457/1.093 | 0.048 | 0.060 | 0.067 | 0.095 | 0.102 | 0.111 | 0.111 | 0.111 | |
| | 0.0522/1.010 | | 0.070 | | 0.083 | | 0.083 | | 0.102 | |

As can be seen, in the coating systems with an outer Al₁₋ₓTiₓN coating layer, which, in any case, already function excellently, additional improvements can still be achieved if the deposition of the Al₁₋ₓTiₓN coating layer takes place in the presence of hydrogen sulfide.

1. A method for producing a coating on an object, in particular a cutting insert such as a cutting plate for machining processes, wherein a coating with one or more coating layers is applied to the object, wherein at least one Al₁₋ₓTiₓN coating layer is deposited using a CVD method, wherein nitrogen in the Al₁₋ₓTiₓN coating layer can be partially substituted, wherein the Al₁₋ₓTiₓN coating layer is deposited in the presence of a sulfur-containing gas.

2. The method according to claim 1, wherein hydrogen sulfide is used as sulfur-containing gas.

3. The method according to claim 1, wherein the Al₁₋ₓTiₓN coating layer is deposited with a hexagonal AlN volume proportion of less than 20 vol %, preferably less than 10 vol %, in particular less than 5 vol %.

4. The method according to claim 1, wherein a proportion of sulfur in the Al₁₋ₓTiₓN coating layer is less than 5 at %, preferably less than 4 at %, in particular less than 3 at %.

5. The method according to claim 1, wherein the Al₁₋ₓTiₓN coating layer is deposited as an outermost coating layer.

6. The method according to claim 1, wherein one or more coating layers are deposited beneath the Al₁₋ₓTiₓN coating layer, wherein preferably all coating layers are deposited using a CVD method.

7. The method according to claim 6, wherein the Al₁₋ₓTiₓN coating layer is deposited at a temperature of 800° C. to 850° C., preferably 810° C. to 830° C.

8. The method according to claim 1, wherein the Al₁₋ₓTiₓN coating layer is deposited from a first mixture of nitrogen, hydrogen, titanium tetrachloride, aluminum trichloride, and hydrogen sulfide and from a second mixture of nitrogen and ammonia.

9. The method according to claim 1, wherein the Al₁₋ₓTiₓN coating layer is at least partially embodied with regions of lamellae, wherein the lamellae preferably have an average size, determined according to Debye-Scherrer, of less than 150 nm, preferably less than 100 nm, in particular less than 80 nm.

10. The method according to claim 1, wherein an object made of a cemented carbide is coated.

11. A coated body having a coating which comprises at least one Al₁₋ₓTiₓN coating layer deposited using a CVD method, wherein nitrogen in the Alix TiₓN layer can be partially substituted, wherein the Al₁₋ₓTiₓN coating layer comprises sulfur.

12. The coated body according to claim 11, wherein the Al₁₋ₓTiₓN coating layer is embodied with a hexagonal AlN volume proportion of less than 20 vol %, preferably less than 10 vol %, in particular less than 5 vol %.

13. The coated body according to claim 11, wherein a proportion of sulfur in the Al₁₋ₓTiₓN coating layer is less than 5 at %, preferably less than 4 at %, in particular less than 3 at %.

14. The coated body according to claim 11, wherein the Al₁₋ₓTiₓN coating layer is at least partially embodied with regions of lamellae, wherein the lamellae preferably have an average size, determined according to Debye-Scherrer, of less than 150 nm, preferably less than 100 nm, in particular less than 80 nm.

15. The coated body according to claim 11, wherein x lies in the range of 0.85 to 0.99.
